(19) United States
(12) Patent Application Publication
(10) Pub. No.: US 2024/0266230 A1
(43) Pub. Date: Aug. 8, 2024

(54) OPTIMIZED FILM DEPOSITION AND ION IMPLANTATION FOR MITIGATION OF STRESS AND DEFORMATION IN SUBSTRATES

(71) Applicant: Applied Materials, Inc., Santa Clara, CA (US)

(72) Inventors: Wonjae Lee, Fremont, CA (US); Pradeep Kumar Subrahmanyan, San Jose, CA (US); D. Jeffrey Lischer, Acton, MA (US); Frank Sinclair, Hartland, ME (US)

(21) Appl. No.: 18/431,834

(22) Filed: Feb. 2, 2024

Related U.S. Application Data
(60) Provisional application No. 63/444,158, filed on Feb. 8, 2023.
(60) Provisional application No. 63/491,170, filed on Mar. 20, 2023.
(60) Provisional application No. 63/502,452, filed on May 16, 2023.
(60) Provisional application No. 63/502,448, filed on May 16, 2023.
(60) Provisional application No. 63/502,447, filed on May 16, 2023.
(60) Provisional application No. 63/511,414, filed on Jun. 30, 2023.

(51) Int. Cl. H01L 21/66; G01B 11/16; H01L 21/3115; H01L 21/67

(52) U.S. Cl. CPC H01L 22/12; G01B 11/16; H01L 21/31155; H01L 21/67288

(57) ABSTRACT

Disclosed systems and techniques are directed to correct an out-of-plane deformation (OPD) of a substrate (e.g., wafer) by identifying, using optical inspection data, a profile of the OPD of the substrate and performing a polynomial decomposition of the profile to determine polynomial coefficients characterizing elemental deformation shapes of the substrate. The techniques further include identifying, based on the polynomial coefficients, characteristics of a stress-compensation layer (SCL) for the substrate and causing the SCL to be deposited on the substrate. The techniques further include performing statistical simulations to identify settings for a non-uniform stress-mitigation irradiation of the SCL, by sampling from one or more statistical distributions associated with previously performed stress-mitigation irradiations, and performing the non-uniform stress-mitigation irradiation of the SCL using the identified settings.

### RELATED APPLICATIONS

This application claims the benefit of U.S. Provisional Patent Application No. 63/444,158, filed Feb. 8, 2023, entitled “Mitigation of stress and deformation in wafers”; U.S. Provisional Patent Application No. 63/491,170, filed Mar. 20, 2023, entitled “Optimized film deposition and ion implantation for mitigation of stress and deformation in wafers”; U.S. Provisional Patent Application No. 63/502,447, filed May 16, 2023, entitled “Mitigation of saddle deformation of wafers using film deposition and edge ion implantation”; U.S. Provisional Patent Application No. 63/502,448, filed May 16, 2023, entitled “Influence function-based mitigation of wafer deformation with film deposition and ion implantation”; U.S. Provisional Patent Application No. 63/502,452, filed May 16, 2023, entitled “Cylindric decomposition for efficient mitigation of wafer deformation with film deposition and ion implantation”; and U.S. Provisional Patent Application No. 63/511,414, filed Jun. 30, 2023, entitled “Wafer stress management for precise wafer-to-wafer bonding,” the contents of which are incorporated by reference in their entirety herein.

### TECHNICAL FIELD

The disclosure pertains to semiconductor manufacturing, including manufacturing of wafers.

### BACKGROUND

Modern semiconducting devices, such as processing circuits, memory devices, light detectors, solar cells, light-emitting semiconductor devices, and the like, are often manufactured on silicon wafers (or other suitable substrates). Wafers may undergo numerous processing operations, such as physical vapor deposition, chemical vapor deposition, etching, photo-masking, polishing, and/or various other operations. In a continuous effort to reduce the cost of semiconductor devices, multi-layer stacks of dies, insulating films, patterned and/or doped semiconducting films, and/or other features are often deposited on a single wafer, resulting in high aspect ratio devices, which are used, e.g., in 3D flash memory devices and other applications. Deposition, patterning, etching, polishing, etc., of stacks of multi-layered structures often result in significant stresses applied to the underlying wafers. Such stresses lead to both an out-of-plane distortion and an in-plane distortion of features supported by the wafers. These distortions result in misalignment of deposited features and can significantly degrade quality of manufactured devices.

### BRIEF DESCRIPTION OF THE DRAWINGS

The present disclosure will be understood more fully from the detailed description given below and from the accompanying drawings of various implementations of the disclosure.

FIGS. 1A-E illustrate schematically a process of stress-correcting the back side-deposited film with an additional ion implantation, according to at least one embodiment.

FIG. 2 illustrates an example Zernike polynomial decomposition of one actual deformation (top left) of a wafer, in arbitrary units, into a paraboloid bow deformation (top right), a saddle deformation (bottom left), and a residual deformation (bottom right), according to at least one embodiment.

FIG. 3 illustrates stress and deformation mitigation in one example wafer using the process disclosed in relation to FIGS. 1A-E, according to at least one embodiment.

FIG. 4 illustrates one example profile of a Gaussian ion beam that can be used for stress and deformation mitigation in wafers, according to at least one embodiment.

FIG. 5 illustrates an example silicon wafer with a Silicon Nitride film deposited thereon having a saddle point deformation, according to at least one embodiment.

FIG. 6 is a flowchart illustrating an example process of mitigation of wafer stress and deformation, in accordance with at least one embodiment.

FIG. 7 is a flowchart illustrating an example process of ion implantation performed for mitigation of wafer deformation and stress, in accordance with at least one embodiment.

FIG. 8A illustrates a dependence of the number of vacancies created as a function of depth (per Angstrom of the distance traveled by ions) by an ion of an implant species in a Silicon Nitride film, in accordance with at least one embodiment.

FIG. 8B illustrates an estimated response of a 200 nm Silicon Nitride film to various doses of an ion of an implant species, in accordance with at least one embodiment.

FIG. 9 illustrates dependence of the number of vacancies created as a function of depth by ions of different types, in accordance with at least one embodiment.

FIG. 10 illustrates a response of a 200 nm Silicon Nitride film as a function of an ion dose of various types of ions, in accordance with at least one embodiment.

FIG. 11 illustrates a distribution of ions with depth for implantation of atoms of different types, in accordance with at least one embodiment.

FIG. 12A illustrates a distribution of implanted ions incident at various angles, in accordance with at least one embodiment.

FIG. 12B illustrates the number of vacancies created (per Angstrom of the distance traveled by ions) with ions incident at various angles, as a function of depth, in accordance with at least one embodiment.

FIG. 12C illustrates a response of an example Silicon Nitride film as a function of an ion dose of various types of ions, in accordance with at least one embodiment.

FIG. 13A illustrates schematically an ion implantation system capable of performing ion implantation into stress-compensation layers, in accordance with at least one embodiment.

FIG. 13B illustrates a delivery of ions to a wafer at an arbitrary angle of incidence by the ion implantation system of FIG. 13A, in accordance to at least one embodiment.

FIG. 14 depicts a block diagram of an example computer system capable of supporting operations of the present disclosure, in accordance with at least one embodiment.

### SUMMARY

In one implementation, disclosed is a method to correct an out-of-plane deformation of a substrate, the method comprising identifying, using optical inspection data, a profile of the out-of-plane deformation of the substrate. The method further includes performing a polynomial decomposition of the identified profile to determine a plurality of polynomial coefficients, each of the plurality of polynomial coefficients characterizing a respective one of a plurality of elemental deformation shapes of the substrate. The method further includes identifying, based on at least a subset of the plurality of polynomial coefficients, one or more characteristics of a stress-compensation layer (SCL) for the substrate. The method further includes causing the SCL to be deposited on the substrate, and performing a plurality of statistical simulations to identify settings for a non-uniform stress-mitigation irradiation of the SCL, wherein performing the plurality of statistical simulations comprises sampling from one or more statistical distributions associated with previously performed stress-mitigation irradiations. The method further includes performing the non-uniform stress-mitigation irradiation of the SCL using the identified settings, wherein the non-uniform stress-mitigation irradiation is performed using at least first settings for a first region of the SCL and second settings for a second region of the SCL.

In another implementation, disclosed is a system that includes a memory and a processing device communicatively coupled to the memory. The processing device is to identify, using optical inspection data, a profile of an out-of-plane deformation of a substrate. The processing device is further to perform a polynomial decomposition of the identified profile to determine a plurality of polynomial coefficients, each of the plurality of polynomial coefficients characterizing a respective one of a plurality of elemental deformation shapes of the substrate. The processing device is further to identify, based on at least a subset of the plurality of polynomial coefficients, one or more characteristics of a stress-compensation layer (SCL) for the substrate. The processing device is further to cause the SCL to be deposited on the substrate. The processing device is further to perform a plurality of statistical simulations to identify settings for a non-uniform stress-mitigation irradiation of the SCL, wherein performing the plurality of statistical simulations comprises sampling from one or more statistical distributions associated with previously performed stress-mitigation irradiations. The processing device is further to perform the non-uniform stress-mitigation irradiation of the SCL using the identified settings, wherein the non-uniform stress-mitigation irradiation is performed using at least first settings for a first region of the SCL and second settings for a second region of the SCL.

In another implementation, disclosed is a semiconductor manufacturing system that includes one or more processing chambers to process a substrate and a computing device. The computing device is to identify, using optical inspection data, a profile of an out-of-plane deformation of a substrate and perform a polynomial decomposition of the identified profile to determine a plurality of polynomial coefficients, each of the plurality of polynomial coefficients characterizing a respective one of a plurality of elemental deformation shapes of the substrate. The computing device is further to identify, based on at least a subset of the plurality of polynomial coefficients, one or more characteristics of a stress-compensation layer (SCL) for the substrate, causing the SCL to be deposited on the substrate. The computing device is further to perform a plurality of statistical simulations to identify settings for a non-uniform stress-mitigation irradiation of the SCL, wherein performing the plurality of statistical simulations comprises sampling from one or more statistical distributions associated with previously performed stress-mitigation irradiations. The computing device is further to perform the non-uniform stress-mitigation irradiation of the SCL using the identified settings, wherein the non-uniform stress-mitigation irradiation is performed using at least first settings for a first region of the SCL and second settings for a second region of the SCL.

In yet another implementation, disclosed is a non-transitory computer-readable memory storing instructions thereon that, when executed by a processing device, cause the processing device to perform operations that include identifying, using optical inspection data, a profile of an out-of-plane deformation of a substrate. The operations further include performing a polynomial decomposition of the identified profile to determine a plurality of polynomial coefficients, each of the plurality of polynomial coefficients characterizing a respective on of a plurality of elemental deformation shapes of the substrate. The operations further include identifying, based on at least a subset of the plurality of polynomial coefficients, one or more characteristics of a stress-compensation layer (SCL) for the substrate. The operations further include causing the SCL to be deposited on the substrate. The operations further include performing a plurality of statistical simulations to identify settings for a non-uniform stress-mitigation irradiation of the SCL, wherein performing the plurality of statistical simulations comprises sampling from one or more statistical distributions associated with previously performed stress-mitigation irradiations. The operations further include performing the non-uniform stress-mitigation irradiation of the SCL using the identified settings, wherein the non-uniform stress-mitigation irradiation is performed using at least first settings for a first region of the SCL and second settings for a second region of the SCL.

### DETAILED DESCRIPTION

Existing technology includes a number of methods to address substrate or wafer deformation. For example, a deformed (warped) substrate, such as silicon wafer, with various films and features deposited on one side (referred to as the front side, top side, or main side herein) can be coated on the other side (referred to as the back side or bottom side herein) with a film that exerts a compression stress or tensile stress on the wafer. Such back side-deposited deformation-correcting film, also referred to as stress-compensation layer herein, usually imparts a uniform (or global) stress to the entire wafer and cannot compensate for local stress modulation and/or anisotropic stress. Additional correction can be achieved by implanting ions into the stress-compensation layer, e.g., using a beam of ions to bombard the stress-compensation layer, to adjust the stress in the stress-compensation layer and, consequently, to further mitigate the deformation of the underlying wafer.

A “wafer,” as used herein, refers to any substrate or material surface formed on a substrate upon which film processing is performed during a fabrication process. For example, a wafer surface on which processing can be performed includes materials such as silicon, silicon oxide, silicon nitride, strained silicon, silicon on insulator, carbon doped silicon oxides, amorphous silicon, doped silicon, germanium, gallium arsenide, glass, sapphire, and any other materials such as metals, metal nitrides, metal alloys, and other conductive materials, depending on the application. In some instances, wafers can include plastic substrates. Wafers include, without limitation, semiconductor wafers. Wafers may be exposed to a pretreatment process to polish, etch, reduce, oxidize, hydroxylate, anneal, UV cure, e-beam cure and/or bake the substrate surface. In addition to film processing directly on the surface of the wafer itself, any of the film processing steps disclosed may also be performed on an underlayer formed on the wafer as disclosed in more detail below, and the term “wafer surface” is intended to include such underlayer as the context indicates. Thus, for example, where a film/layer or partial film/layer has been deposited onto a wafer surface, the exposed surface of the newly deposited film/layer becomes the wafer surface. In some embodiments, wafers have a thickness in the range of 0.25 mm to 1.5 mm, or in the range of 0.5 mm to 1.25 mm, in the range of 0.75 mm to 1.0 mm, or more. In some embodiments, wafers have diameter of about 10 cm, 20 cm, 30 cm, or more.

Deposition of stress-compensation layers with ion implantation can be quite efficient in correcting stresses that are uniform and isotropic, σₓₓ≈σ_{yy}. On the other hand, mitigating stresses that vary with location x, y on the wafer, σⱼₖ(x, y), stresses that are anisotropic, σₓₓ≠σ_{yy}, or both is a much more challenging problem. Certain feature patterns can result in stresses that are compressive along one direction, e.g., σₓₓ>0, and tensile along a perpendicular direction, σ_{yy}<0, e.g., as illustrated in FIG. 5. Such features can arise, for example, in stacks of materials with directional patterning, e.g., patterning of wordlines in flash memory devices. Correcting the ensuing anisotropic and/or non-uniform stresses and the resulting wafer deformations remains a difficult task.

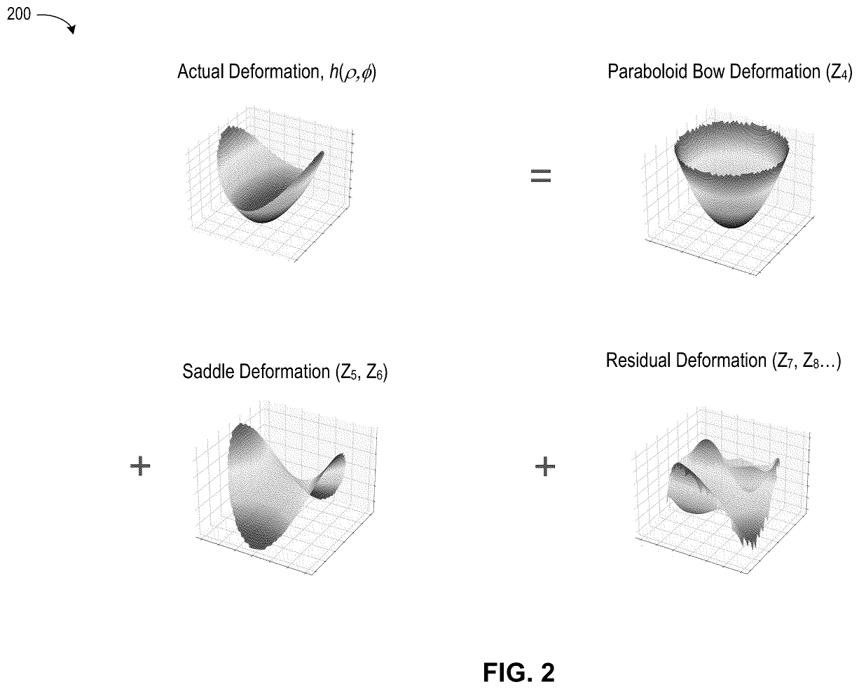

Aspects and implementations of the present disclosure address these and other challenges of the modern semiconductor manufacturing technology by providing for systems and techniques that can mitigate non-uniform and/or anisotropic stresses and deformations of wafers. In one embodiment, a vertical profile of wafer deformation z=h(r, ϕ) may be measured using optical metrology techniques. For example, an interferogram of the profile h(r, ϕ) can be obtained using optical interferometry measurements. The wafer profile h(r, ϕ) can then be represented via a number of parameters that qualitatively and quantitatively characterize geometry of the wafer deformation. In some embodiments, a set of Zernike (or a similar set of) polynomials may be used to represent the wafer profile,

$$h ( r , ϕ ) = {\sum }_{j} {A}_{j} {Z}_{j} ( r , ϕ ) ,$$

where r is the radial coordinate and ϕ is the polar angle coordinate within the (average) plane of the wafer. Consecutive coefficients A₁, A₂, A₃, A₄ . . . represent weights of specific geometric features (elemental deformations) of the wafer described by the corresponding Zernike polynomials Z₁(r, ϕ), Z₂(r, ϕ), Z₃(r, ϕ), Z₄(r, ϕ) . . . . The first three coefficients are of less interest as they describe a uniform shift of the wafer (coefficient A₁, associated with the Z₁(r, ϕ)=1 polynomial), a deformation-free x-tilt that amounts to a rotation around the y-axis (coefficient A₂, associated with the Z₂(r, ϕ)=2r cos ϕ polynomial), and a deformation-free x-tilt that amounts to a rotation around the x-axis (coefficient A₃, associated with the Z₃(r, ϕ)=2r sin ϕ polynomial) that can be eliminated by a realignment of the coordinate axis. The fourth coefficient A₄ is associated with Z₄(r, ϕ)=\sqrt{3}(2r²−1) and characterizes an isotropic paraboloid deformation (“bow”). The fifth A₅ and the sixth A₆ coefficients are associated with Z₅(r, ϕ)=\sqrt{6}r² sin 2ϕ and Z₆ (r, ϕ)=\sqrt{6}r² cos 2ϕ polynomials, respectively, and characterize a saddle-type deformation. The A₅ coefficient characterizes a saddle shape that curves down (A₅>0) or up (A₅<0) along the diagonal y=x and curves up (A₅>0) or down (A₅<0) along the diagonal y=−x. The A₆ coefficient characterizes a saddle shape that curves up (A₆>0) or down (A₆<0) along the x-axis and curves down (A₆>0) or up (A₆<0) along the y-axis. The higher coefficients A₇, A₈, etc., characterize progressively faster variations of the wafer deformation h(r, ϕ) along the radial direction, along the azimuthal direction, or both and collectively represent a residual deformation, hᵣₑₛ(r, ϕ)=h(r, ϕ)−Σⱼ₌₄⁶AⱼZⱼ(r, ϕ). FIG. 2 illustrates an example Zernike polynomial decomposition 200 of one actual deformation h(r, ϕ) (top left) of a wafer, in arbitrary units, into a paraboloid bow deformation A₄Z₄(r, ϕ) (top right), a saddle deformation A₅Z₅(r, ϕ)+A₆Z₆(r, ϕ) (bottom left), and a residual deformation, hᵣₑₛ(r, ϕ) (bottom right), according to at least one embodiment.

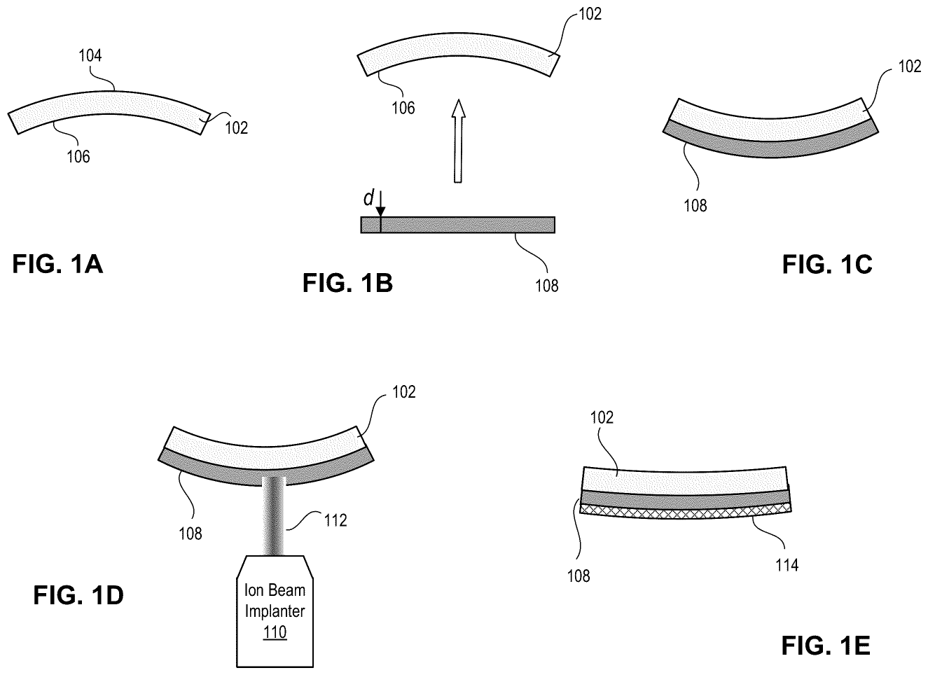

In some embodiments, selection of a thickness d of the deformation-compensating film can be made based on a value of the paraboloid bow coefficient A₄. FIGS. 1A-E illustrate schematically a process of stress-correcting the back side-deposited film with an additional ion implantation, according to at least one embodiment. FIG. 1A depicts a wafer 102 having a deformation, which can include a paraboloid bow deformation (with negative coefficient A₄<0) and other deformations, e.g., a saddle deformation and a residual deformations (both not shown in FIGS. 1A-D for conciseness and ease of viewing). Wafer 102 has a front side 104 and a back side 106. Any number of features (e.g., deposition and/or etching patterns), dies, photo-masks, and/or any other structures can be deposited on or etched in the front side 104. In some embodiments, back side 106 can be free from deposited/etched features/structures. In some embodiments, back side 106 can also have one or more deposited/etched features/structures. FIG. 1B illustrates schematically deposition of a stress-compensation layer on the back side of wafer 102. In some embodiments, stress-compensation layer 108 can include one or more films of different materials. Individual films may have a thickness in the range of 10 nm to 200 nm, or in the range of 20 nm to 180 nm, or in the range of 30 nm to 160 nm, or in the range of 40 nm to 140 nm, or more. A total thickness of the stress-compensating layer may be up to several microns or even more. In some embodiments, stress-compensation layer 108 is deposited at a temperature in the range of 100° C. to 500° C. or more.

A material (type) of stress-compensation layer 108 can be selected based on the sign of coefficient A₄. For example, for a negative bow, A₄<0, and stress-compensation layer 108 may be selected to have a tensile stress (as illustrated in FIGS. 1A-E). For silicon wafers, such a film can be a silicon nitride (Si₃N₄) film. Conversely, for a positive bow, A₄>0, and stress-compensation layer 108 may be selected to have a tensile stress (not shown in FIGS. 1A-E). Stress-compensation layer 108 can be deposited using any suitable deposition techniques including physical vapor deposition (e.g., sputtering), chemical vapor deposition (e.g., plasma-assisted deposition), epitaxy, exfoliation, and/or the like. Deposition can be performed at room temperature or at temperatures different from room temperature (e.g., at an elevated temperature). In some embodiments, a thickness d of stress-compensation layer 108 can be selected to overcorrect the deformation to some degree, e.g., as illustrated in FIG. 1C where a negative paraboloid bow becomes a positive paraboloid bow. The thickness-dependent paraboloid bow correction A_{corr}(d) changes wafer deformation from h(r, ϕ) to h_{corr}(r, ϕ):

$${h}_{corr} ( r , ϕ ) = h ( r , ϕ ) + {A}_{corr} ( d ) \cdot {Z}_{4} ( r , ϕ ) .$$

The overcorrection is chosen in conjunction with the implant species, energy, and dose to ensure maximum entitlement from the stress compensation. The overcorrection makes the combined structure of wafer 102 and stress-compensation layer 108 susceptible to further control of stress (and thus deformation of the wafer h_{corr}(r, ϕ)). As illustrated in FIG. 1D, an ion beam implanter 110 can generate an ion beam 112 that strikes stress-compensation layer 108 and deposits ions therein. Ion beam 112 can carry silicon ions, phosphorus ions, argon ions, neon ions, xenon ions, krypton ions, and/or the like. In some embodiments, the energy and type of ions in ion beam 112 can be selected to limit the implanted ions to the volume of stress-compensation layer 108 without allowing the ions to reach wafer 102. Ions that lodge in stress-compensation layer 108 create substitution defects therein. Additionally, the ions leave a trail of vacancy defects along paths of propagation in stress-compensation layer 108. The substitution defects and/or vacancies modify (e.g., reduce) stress in stress-compensation layer 108 and can reduce the degree of stress overcorrection caused by the film deposition. This causes the combination of wafer 102 and stress-compensation layer 108 to flatten.

Although, for the sake of specificity, a stress-mitigation beam that is used to modify the stress in stress-compensation layer 108 is referred to as ion beam (e.g., ion beam 112) throughout this disclosure, the stress-mitigation beam can include other matter particles (e.g., electrons), electromagnetic waves (e.g., UV light, visible light, infrared light, etc.), and/or a suitable combination thereof. The stress-mitigation beam strikes stress-compensation layer 108 and changes the bonding network of stress-compensation layer 108. For example, the stress-mitigation beam of low energy may interact with surface atoms of stress-compensation layer 108, e.g., removing some of the surface atoms, effectively implementing etching of surface regions of stress-compensation layer 108. The effectiveness of such etching may be controlled by a choice of ion species/radicals/ambient gasses. In another example, the stress-mitigation beam of high energy can deposit ions inside stress-compensation layer 108. Ions and/or photons can break bonds of the bonding network (or crystal lattice) of stress-compensation layer 108 forming vacancies therein, and can further cause annealing due to local heating, UV curing, and/or other effects.

In some embodiments, the number of ions ΔNᵢ deposited per small area ΔA=ΔxΔy of the wafer may be determined using simulations (performed as described in more detail below) based on the local value of the corrected deformation h_{corr}(r, ϕ), which may include a saddle deformation, a residual deformation, and the part of the paraboloid bow deformation A_{corr}(d)+A₄ that has been overcorrected by the deposition of stress-compensation layer 108. The desired local density ΔNᵢ/ΔxΔy of the ions can be delivered by controlling the scanning velocity v of ion beam 112. In some embodiments, ion beam 112 has a profile that can be approximated with a Gaussian function, e.g., the ion flux j(φ=j₀ exp(−x²/a²−y²/b²), where x and y are Cartesian coordinates, j₀ is the maximum ion flux at the center of the beam, and a and b is are characteristic spreads of the beam along the x-axis and y-axis, respectively. Correspondingly, a point that is located at distance y from the path of the center of the beam receives an ion dose that includes the following number of ions:

$$\frac{Δ {N}_{i}}{Δ x Δ y} = \frac{{j}_{0}}{v} {{\int }^{∞}}_{- ∞} {dxe}^{- {x}^{2} / {a}^{2} - {y}^{2} / {b}^{2}} = \frac{{j}_{0} \sqrt{π}}{va} {e}^{- {y}^{2} / {b}^{2}} .$$

Correspondingly, by reducing the scanning velocity v, the number of ions received by various regions of stress-compensation layer 108 can be increased, and vice versa. Additionally, ion beam 112 can perform multiple scans with different offsets y so that various points of stress-compensation layer 108 receive multiple doses of ions with different factors e^{-y}^{²}^{/b}^{²} that can average to a target dose. For example, after n passes of ion beam implanter 110, each made with a respective velocity vₖ at a different distance yₖ from the center of ion beam 112 to the area ΔxΔy, the total dose of ions received by this area will be

$$\frac{Δ {N}_{i}}{Δ x Δ y} {\vert}_{total} = {j}_{0} \sqrt{π} {\sum }_{k = 1}^{n} \frac{{e}^{- {y}_{k}^{2} / {b}^{2}}}{{av}_{k}} .$$

As illustrated in FIG. 1E, an implantation layer 114 formed as part of stress-compensation layer 108 results in a significant mitigation of deformation of wafer 102, and in particular its saddle and residual portions.

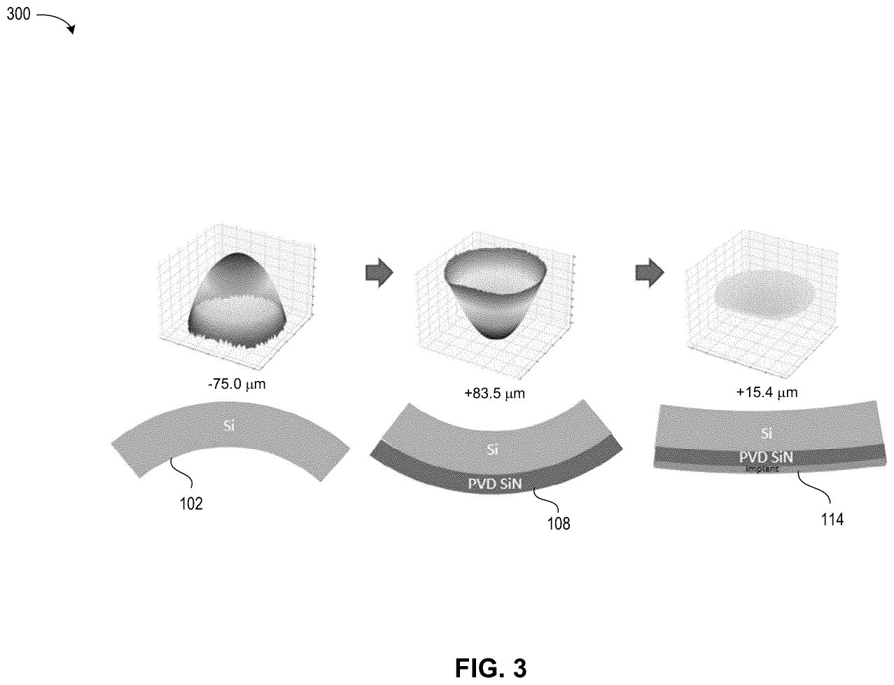

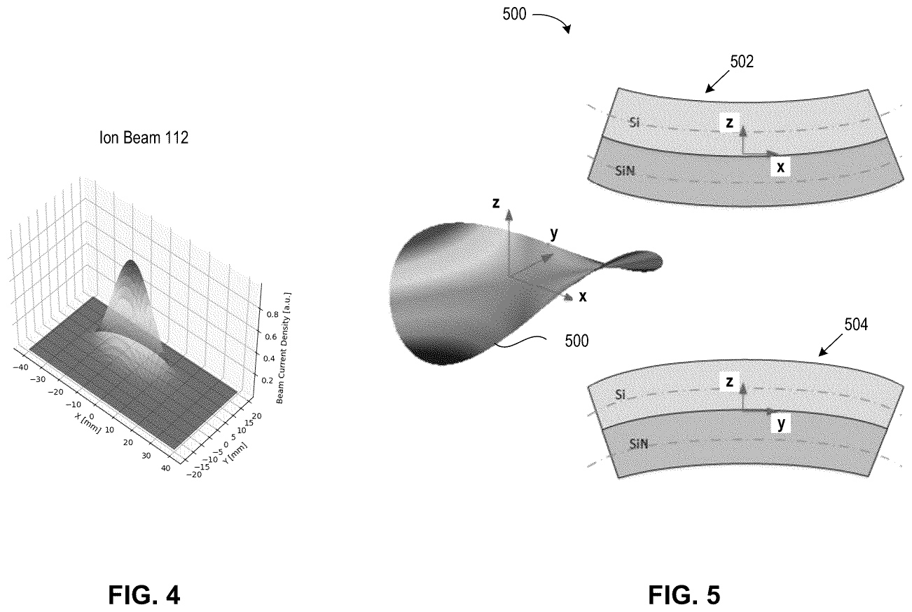

FIG. 3 illustrates stress and deformation mitigation 300 in one example wafer using the process disclosed in relation to FIGS. 1A-E, according to at least one embodiment. As depicted in FIG. 3, a 30 cm Silicon wafer 102 with the maximum negative deformation of −75.0 μm is first overcorrected to the maximum deformation of +83.5 μm using a Silicon Nitride tensile stress-compensation layer 108. The stresses in stress-compensation layer 108 are then reduced by the formation of implantation layer 114 with an ion beam, resulting in a final maximum deformation of +15.4 μm. FIG. 4 illustrates one example profile of a Gaussian ion beam 112 that can be used for stress and deformation mitigation in wafers, according to at least one embodiment.

The techniques of strain and deformation mitigation illustrated in FIGS. 1-3 can also be applied to a wafer having a complex deformation in which stress tensor components σₓₓ and σ_{yy} have different sign causing the wafer to have a saddle deformation. FIG. 5 illustrates an example wafer 500 (e.g., a silicon wafer with a Silicon Nitride film deposited thereon) having a saddle point deformation, according to at least one embodiment. As seen in the cross-sectional xz view 502, the stress component σₓₓ may be lower in the wafer (the top layer) than in the film (the bottom layer) deposited on the back side of the wafer. Conversely, as illustrated with the cross-sectional yz view 504, the stress component σ_{yy} may be higher in the wafer than in the film. In some embodiments, the state of stress in the wafer may be represented by the location-dependent stress tensor which may be approximated as,

$$σ ( x , y ) = ( \begin{matrix}{σ}_{xx} & {σ}_{xy} & {σ}_{xz} \\ {σ}_{yx} & {σ}_{yy} & {σ}_{yz} \\ {σ}_{zx} & {σ}_{zy} & {σ}_{zz}\end{matrix} ) \approx ( \begin{matrix}{σ}_{xx} & 0 & 0 \\ 0 & {σ}_{yy} & 0 \\ 0 & 0 & 0\end{matrix} ) .$$

This structure of the stress tensor is usually a good approximation since the wafer is typically in a state of pure bending and independent of the shear stresses that are represented by the off-diagonal terms in the stress tensor. Correction of the saddle shape requires special handling in the computation of the dose map and optimization to ensure that additional residual terms are not introduced into the wafer as a result.

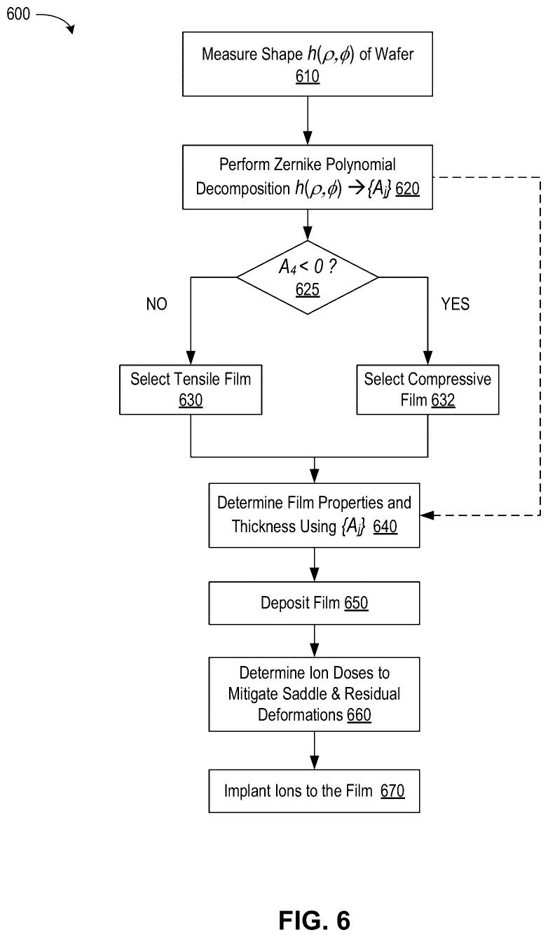

FIG. 6 is a flowchart illustrating an example process 600 of mitigation of wafer stress and deformation, in accordance with at least one embodiment. Process 600 can be performed using a semiconductor manufacturing system that includes one or more processing chambers, e.g., deposition chamber(s), plasma chamber(s), etching chamber(s), polishing chamber(s), film removal chamber(s), beam irradiation chamber(s), optical inspection chamber(s), and/or the like. The processing chambers can be connected to one or more transfer chambers, which can be equipped with robot(s) to handle wafers, e.g., moving wafers into and out of processing chambers. The transfer chamber can further be connected to a load-lock chamber (Front-End Interface) that can be coupled to one or more Front Opening Unified Pod carriers that hold bare wafers, processed wafers, partially processed wafers, and/or the like. Operations performed by the semiconductor manufacturing system, including any, some or all operations of process 600, can be performed responsive to instructions issued by a suitable computing device having a processing logic and memory to store the instructions.

At block 610, process 600 includes measuring the shape of a wafer, e.g., a displacement of a surface (e.g., top surface) of a wafer as a function of some in-plane coordinates, e.g., polar coordinates z=h(r, ϕ), Cartesian coordinates, z=h(x, y), or any other suitable coordinates. At block 620, process 600 includes decomposition of the determined shape over a suitable set of polynomials, e.g., Zernike polynomials, and obtaining a set of polynomial expansion coefficients, {Aⱼ}=(A₁, A₂, A₃) A₄, A₅, A₆, A₇ . . . , each coefficient in the set characterizing a degree of presence of a particular elemental geometric shape in the wafer's deformation. At a decision-making block 625, process 600 includes determining what type of a deformation-compensating film is to be used with the wafer. In some embodiments, the decision can be made based on a coefficient that determines a degree of parabolicity of the deformation, e.g., coefficient A₄. If the wafer is curved downwards (towards the back side of the wafer), process 600 can select, at block 630, a compressive film for back side deposition and stress mitigation in the wafer. If the wafer is curved upward (towards the top side of the wafer), process 600 can select, at block 632, a tensile film for back side deposition and stress mitigation.

At block 640, process 600 can continue with determining a type of material for the deformation-compensating film to be deposited and thickness d of the film. As illustrated with the dashed arrow in FIG. 6, in some embodiments, determination at block 640 can be made based on multiple expansion coefficients (more than just the paraboloid bow coefficient A₄) from the set {Aⱼ} or the full profile h(r, ϕ). In one specific non-limiting example, the thickness d can be determined as follows. First, a target paraboloid deformation Ã₄ can be determined that is sufficient to overcompensate for the measured wafer deformation, e.g., for h(r, ϕ)<0, the following condition can be satisfied:

$${\tilde{A}}_{4} {Z}_{4} ( ρ , ϕ ) + h ( r , ϕ ) ≡ ( {\tilde{A}}_{4} + {A}_{4} ) {Z}_{4} ( ρ , ϕ ) + {A}_{5} {Z}_{5} ( ρ , ϕ ) + {A}_{5} {Z}_{6} ( ρ , ϕ ) + … > 0.$$

In other words, the target paraboloid deformation Ã₄ can be chosen sufficiently large to compensate for the paraboloid deformation (A₄), saddle deformation (A₅ and A₆) and the residual deformation (A₇, and higher coefficients). In some embodiments, the target paraboloid deformation Ã₄ can be selected with at least an excess magnitude A_{E} over the minimum needed to overcompensate for the wafer deformation, e.g.,

$${\tilde{A}}_{4} {Z}_{4} ( ρ , ϕ ) + h ( r , ϕ ) > {A}_{E} {Z}_{4} ( ρ , ϕ ) .$$

The excess magnitude A_{E} can be empirically selected and can depend on the specific material used for the deformation-compensating film.

Once the target paraboloid deformation Ã₄ has been determined, the thickness of the film d can be selected using a calibration data that tabulates or otherwise defines a function d=ƒ(Ã₄). In some embodiments, the function ƒ(Ã₄) can be a non-linear function. In some embodiments, the function ƒ(Ã₄) can be a linear function, d=αÃ₄, with a coefficient of proportionality a determined based on mathematical modeling of elastic equations, empirical calibration, or any combination thereof. At block 650, the deformation-compensating film of the selected thickness d is deposited on the back side of the wafer. At block 660, doses for ion implantation are computed. In some embodiments, ion doses are computed based on the expansion coefficients A₅, A₆ (to compensate for the saddle deformation) and A₇, A₈ . . . (to compensate for the residual deformation). In some embodiments, ion doses are computed following a new measurement of the deformation of the wafer that is performed after block 650 (not shown in FIG. 6) and after a re-determination of the expansion coefficients {Aⱼ}. The computed ion doses are then imparted to the deposited film at block 670.

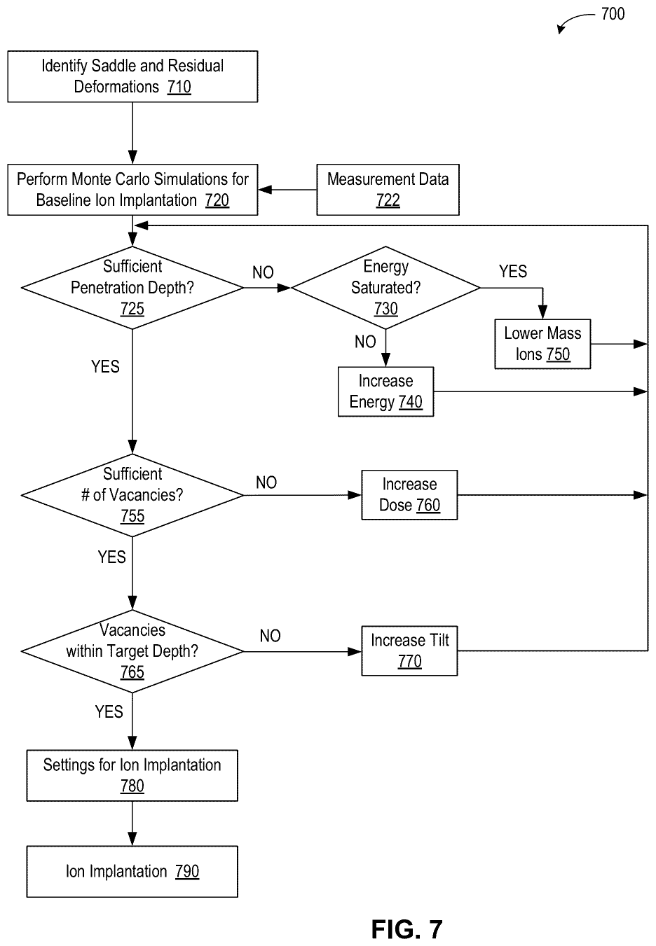

FIG. 7 is a flowchart illustrating an example process 700 of ion implantation performed for mitigation of wafer deformation and stress, in accordance with at least one embodiment. Process 700 can be performed as part of blocks 660-670 of process 600. At block 710, process 700 can include identifying a saddle deformation and a residual deformation of a wafer after stress-compensation layer has been deposited on the wafer. In some embodiments, the saddle deformation (e.g., Zernike coefficients A₅, A₆) and the residual deformation (e.g., Zernike coefficients A₇, A₈ . . . ) can be estimated using profilometry measurements performed prior to the film deposition and based on the assumption that while the paraboloid bow deformation is strongly affected by the deposition of the film, the saddle deformation and the residual deformation remain can largely unaffected by the placement of the film. In some embodiments, the saddle deformation and the residual deformation are determined based on profilometry measurements performed after the deposition of the film, for additional accuracy.

At block 720, process 700 can include performing Monte Carlo simulations for the wafer and the deposited film. The Monte Carlo simulations can be performed for a film made of the actual material (or a material compound) used in deposition and having a specific thickness d. An initial Monte Carlo simulation can be performed for specific baseline (default) conditions of the ion implantation (e.g., default settings of an ion implantation apparatus). The baseline conditions can include a default type of ions, a default energy of ions, a default dose of ions to be imparted to the film (e.g., a default velocity of scanning and a default scanning pattern), and the like. The Monte Carlo simulations can use measurement data (calibration data) 722 collected for actual ion implantation performed for various ion energies, types of ions, types and materials of deposition films, angles of ion incidence on the films, and/or the like.

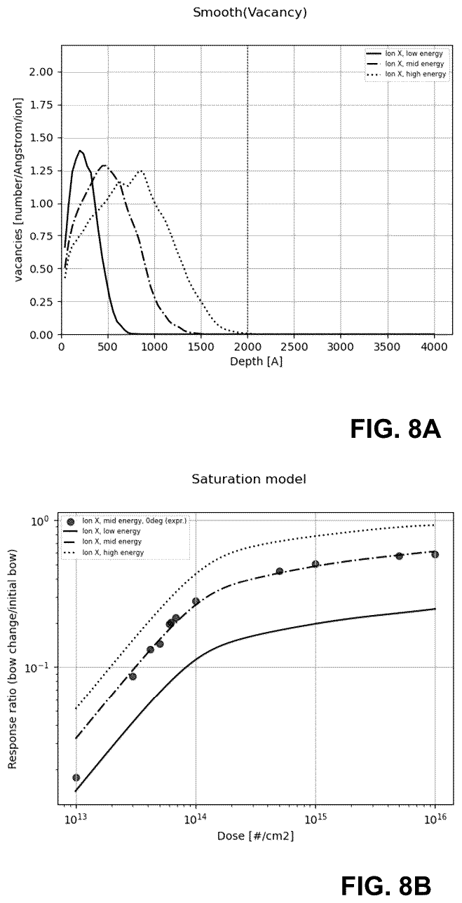

Measurement data 722 can include characterization of the number of vacancies created by ions of different types and energies. FIG. 8A illustrates a dependence of the number of vacancies created as a function of depth (per Angstrom of the distance traveled by ions) by an ion of an implant species in a Silicon Nitride film, in accordance with at least one embodiment. Different curves correspond to different energies of Phosphorus ions, e.g., 30 keV (low energy, solid line), 65 keV (mid-energy, dot-dashed line), and 100 keV (high energy, dotted line). It should be understood that this example is non-limiting and that many different species of ions (such as Silicon, Arsenic, Gallium, Argon, Boron, Carbon, and the like) at different energies (e.g., 10-500 keV or more) can be used. With increasing energy of the ions, the number of created vacancies shifts towards larger depths. FIG. 8B illustrates an estimated response of a 200 nm Silicon Nitride film to various doses of an ion of an implant species, in accordance with at least one embodiment. The estimated response (the ratio of the bow change to the initial bow) characterizes, in one non-limiting example, stress (e.g., tensile stress) induced in the film by implantation of various ion doses from about 1⁰¹⁴ ions/cm² to about 10¹⁶ ions/cm² for different energies of Phosphorus ions, e.g., 30 keV (low energy, solid line), 65 keV (mid-energy, dot-dashed line), and 100 keV (high energy, dotted line). The response is linear (with the slope increasing with the energy of ions) for low ion doses and tends to saturation at the ion dose increases.

As illustrated in FIG. 8A, a significant portion of the ions with mid-energies and large energies can pass through a 100 nm film and lodge in the wafer as substitution impurities. This can detrimentally affect electrical (or mechanical) properties of the wafer. Such situations can be prevented by changing the type of the ions. In some embodiments, ion implantation can be performed with ions of the same type as the material of the wafer, e.g., with Silicon ions.

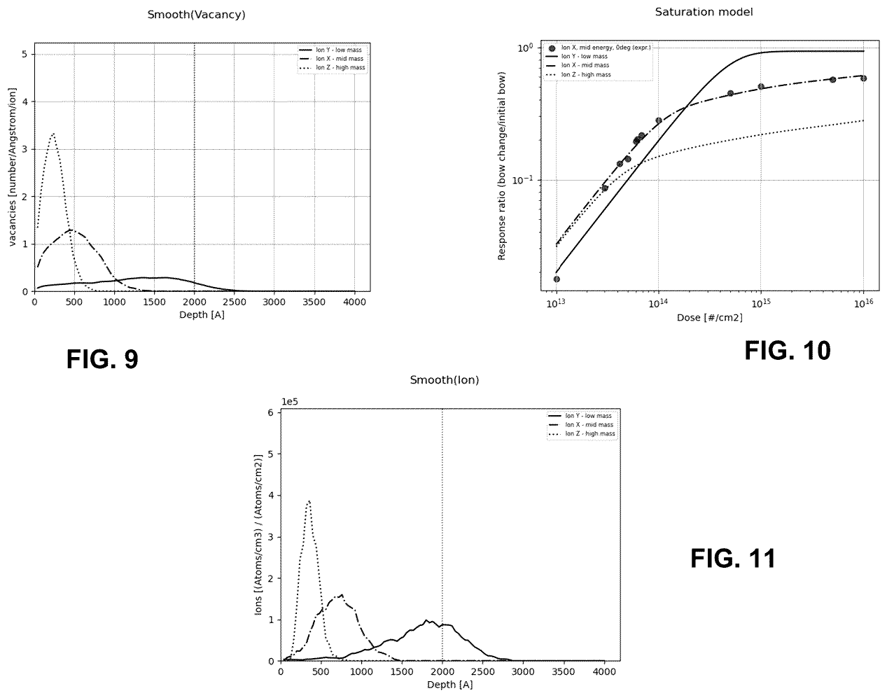

FIG. 9 illustrates dependence of the number of vacancies created as a function of depth by ions of different types, in accordance with at least one embodiment. Different curves correspond to different species of ions with AMUs ranging from 10 (low mass), 30 (mid mass), 100 (high mass); all ions having the same energy. It should be understood that these examples are non-limiting and that many other species of ions may be used (e.g., Hydrogen, Silicon, Arsenic, Gallium, Argon, Boron, Carbon, Krypton, and the like) at different energies (e.g., 10-500 keV or more) can be used.

FIG. 10 illustrates a response of a 200 nm Silicon Nitride film as a function of an ion dose of various types of ions, in accordance with at least one embodiment.

FIG. 11 illustrates a distribution of ions with depth for implantation of atoms of different types, in accordance with at least one embodiment. The distribution of ions is measured in units of the number of implanted atoms per cubic centimeter.

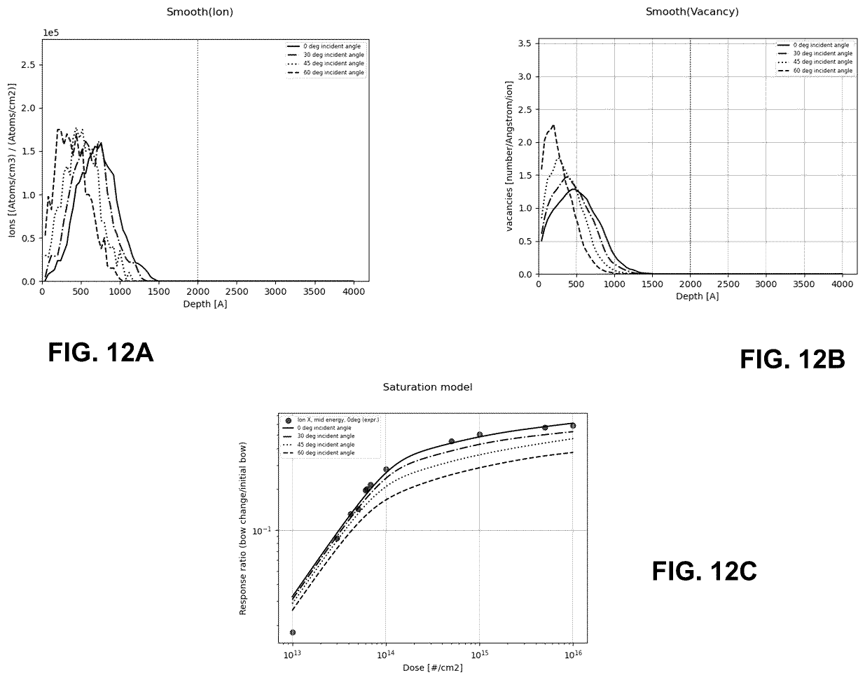

Measurement data 722 can further include characterization of the number of vacancies created by ions incident at different angles. FIG. 12A illustrates a distribution of implanted ions incident at various angles, in accordance with at least one embodiment. Different curves correspond to Phosphorous ions incident at angles of 0 degrees (normal incidence), 30 degrees, 45 degrees, and 60 degrees. FIG. 12B illustrates the number of vacancies created (per Angstrom of the distance traveled by ions) with ions incident at various angles, as a function of depth, in accordance with at least one embodiment. Different curves correspond to Phosphorous ions incident at angles of 0 degrees, 30 degrees, 45 degrees, and 60 degrees. As illustrated in FIG. 12A and FIG. 12B, increasing the angle of incidence reduces the depth of ion implantation and increases the number of ions deposited and vacancies created within a shallow region near the surface of the wafer. FIG. 12C illustrates a response of a 200 nm Silicon Nitride film as a function of an ion dose of various types of ions, in accordance with at least one embodiment.

With a continuing reference to FIG. 7, the Monte Carlo simulations performed at block 720 can use the above-described measurement data 722 as well as any additional data. In some embodiments, measurement data 722 can be statistically preprocessed. For example, various measurement data (e.g., the data illustrated in FIGS. 8-12 and similar data) can be collected for multiple film materials, types of ions, angles of incidence, and/or other parameters. The statistically processed measurement data can be stored (e.g., in a memory of a processing device performing the Monte Carlo simulations) in the form of probability distributions of various quantities, included but not limited to:
distribution of the density of ion implantation with depth for different ion types, ion energies, angles of incidence;
distribution of the number of vacancies produced at different depths (per unit of length of travel of the ions) for different ion types, ion energies, and angles of incidence;
distribution of stresses created by implanted ions for different densities of ion implantation and/or the number of produces vacancies.

Performing the Monte Carlo simulation can include sampling from the stored distributions and identifying a likelihood that a target stress mitigation (e.g., determined as described above in conjunction with process 600 illustrated in FIG. 6) will be achieved with the default settings of ion implantation for a given deformation-compensating film of thickness d. Process 700 can include several verification operations designed to determine whether the target stress can be achieved without detrimentally affecting properties of the wafer. For example, at block 725, process 700 can include verifying if the penetration depth of the selected (e.g., default) type of ions is sufficient. For example, the penetration depth is to be at least a certain fraction of the thickness of the stress-compensation layer, e.g., 20%, 30%, 50%, 80%, or more of that thickness. In some embodiments the penetration depth can be up to 100%, of the thickness. If the energy is insufficient, process 700 can include checking, at block 730, if ion beam implanter 110 is capable of outputting ions of a higher energy. If higher energies are available, process 700 can continue with increasing the energy of ions (block 740) and repeating Monte Carlo simulations for the increased energy. If the maximum energy of ion beam implanter 110 has already been reached, process 700 can continue with replacing (block 750) ions with ions of a different type, e.g., replacing Silicon ions with Boron, Carbon, Fluorine, etc., ions, and repeating Monte Carlo simulations for the ions of the new type.

At block 755, process 700 can include verifying if the number of expected formed vacancies is sufficient. To verify sufficiency, process 700 can assess stress mitigation caused by formed vacancies. In one embodiment, process 700 can begin at some value of stress in the stress-compensation layer, e.g., −3.0 GPa or some other suitable value (negative sign indicating compressive stress) and use ion implants to mitigate this stress towards a neutral point, 0.0 GPa at various locales of the stress-compensation layer.

If the number of vacancies is insufficient, process 700 can include increasing a dose of ions (at block 760) and repeating Monte Carlo simulations for the increased dose.

At block 765, process 700 can include verifying that the vacancies are going to be placed within a target depth, e.g., the thickness d of the film or a certain fraction of the film, such as 0.8d, 0.7d, 0.5d, or some other value empirically set to prevent ions from penetrating into the wafer and affecting wafer's properties. If the vacancies are formed at depths that exceed the target depth, process 700 can include (at block 770) increasing an angle of incidence (tilt of ion beam implanter 110) dose of ions to keep vacancies (as well as substitution impurities) to a shallower region of the film.

Blocks 725-765 can be repeated multiple times until the Monte Carlo simulations predict that the desired stress mitigation can be achieved, e.g., that the reduction in the tensile stress of the deformation-compensating film is such that the saddle deformation and the residual deformation of the wafer are eliminated or at least reduced to an acceptable tolerance. The final settings for ion implantation (at block 780) determined from the Monte Carlo simulations can then be used for ion implantation (at block 790).

To compensate for the saddle deformation and the residual deformation, the Monte Carlo simulations can be performed separately for different regions of the wafer to ensure that location-dependent local stresses σₓₓ(x, y) and σ_{yy}(x, y) are mitigated to the same or approximately the same uniform baseline value σ_{base}. Correspondingly, different regions of the deformation-compensating film can receive different doses of ions. In some instances, different regions of the deformation-compensating film can receive ions with different directions of incidence.

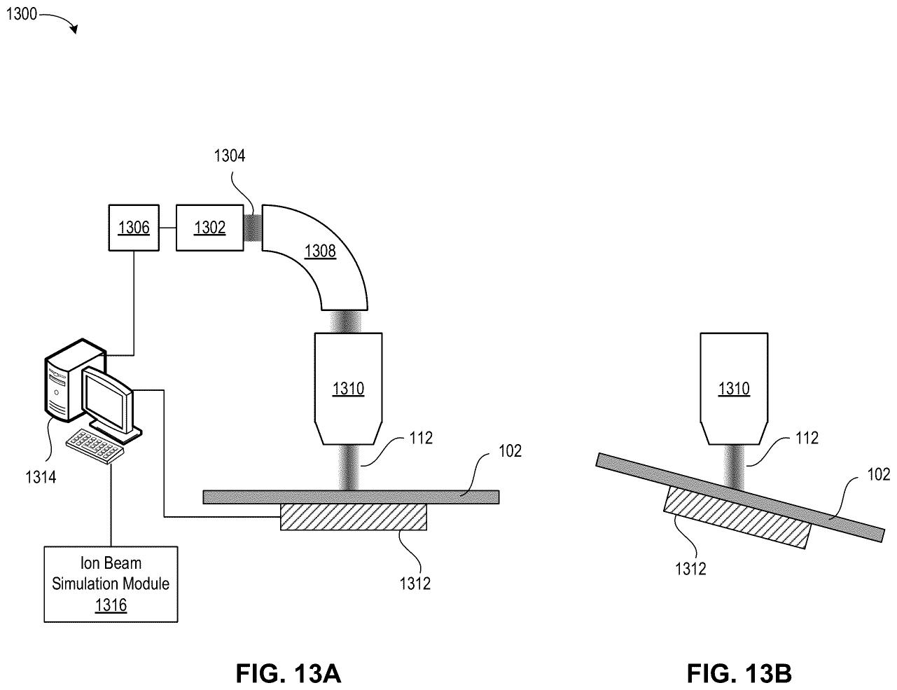

FIG. 13A illustrates schematically an ion implantation system 1300 capable of performing ion implantation into stress-compensation layers, in accordance with at least one embodiment. Ion implantation system 1300 can be or include ion beam implanter 110 of FIG. 1. Although, for the sake of specificity, a stress-mitigation beam that is used to modify the stress in a stress-compensation layer 108 is referred to as ion beam (e.g., ion beam 112), in some embodiments, the stress-mitigation beam can include other matter particles (e.g., electrons), electromagnetic waves (e.g., UV light, visible light, infrared light, etc.), and/or a suitable combination thereof. Ion implantation system 1300 can include and ion source 1302 for producing an ion beam 1304. Ion source 1302 can include a chamber for generating ions (e.g., a plasma chamber). Ion source 1302 can be powered by a power source 1306 and can include an extraction electrode assembly (not shown). Ion implantation system 1300 can include a mass spectrometer 1308 and a collimating and focusing column 1310. Collimating and focusing column 1310 can direct ion beam 112 to wafer 102. Wafer 102 can be supported by a support stage 1312. In some embodiments, support stage 1312 and wafer 102 can remain stationary during scanning of wafer 102 by ion beam 112 while components of ion implantations system 1300 can be repositioned relative to wafer 102. In some embodiments, ion implantations system 1300 can be stationary while support stage 1312 can reposition wafer 102. Scanning with ion beam 112 can occur along multiple directions, e.g., along x-axis and along y-axis according to any suitable predetermined pattern, e.g., back-and forth along x-axis, in a spiral pattern, and so on. In various embodiments, ion beam 112 can be scanned at a frequency of several Hz, tens of Hz, hundreds of Hz, thousands of Hz, or more.

Operations of ion implantation system 1300 can be controlled by a controller 1314, which can include any suitable computing device, microcontroller, or any other processing device having a processor, e.g., a central processing unit (CPU), a field-programmable gate array (FPGA), an application-specific integration circuit (ASIC), and/or the like, and a memory device, e.g., a random-access memory (RAM), read-only memory (ROM), flash memory, and/or the like or any combination thereof. Controller 1314 can control operations of power source 1306, support stage 1312, and/or various other components and modules of ion implantation system 1300. Controller 1314 can include an ion beam simulation module 1316 capable of performing simulations as described above in conjunction with FIGS. 7-12. In some embodiments, e.g., as illustrated in FIG. 13B, support stage 1312 can impart a tilt, e.g., in one or two spatial directions to wafer 102 to change an angle of incidence of ion beam 112 relative to wafer 102. In some embodiments, instead of tilting wafer 102, controller 1314 can cause a tilt of ion implantation system 1300 relative to wafer 102.

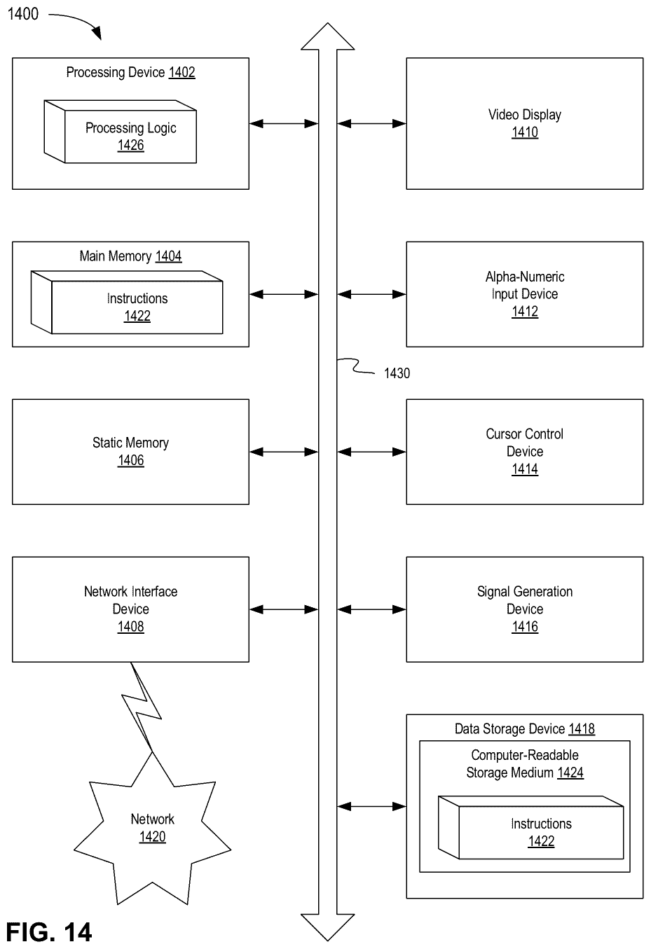

FIG. 14 depicts a block diagram of an example computer system 1400 capable of supporting operations of the present disclosure, in accordance with at least one embodiment. In various illustrative examples, example computer system 1400 may be or include controller 1314 of FIG. 13. Example computer system 1400 may be connected to other computer systems in a LAN, an intranet, an extranet, and/or the Internet. Computer system 1400 may operate in the capacity of a server in a client-server network environment. Computer system 1400 may be a personal computer (PC), a set-top box (STB), a server, a network router, switch or bridge, or any device capable of executing a set of instructions (sequential or otherwise) that specify actions to be taken by that device. Further, while only a single example computer system is illustrated, the term “computer” shall also be taken to include any collection of computers that individually or jointly execute a set (or multiple sets) of instructions to perform any one or more of the methods discussed herein.

Example computer system 1400 may include a processing device 1402 (also referred to as a processor or CPU), a main memory 1404 (e.g., read-only memory (ROM), flash memory, dynamic random access memory (DRAM) such as synchronous DRAM (SDRAM), etc.), a static memory 1406 (e.g., flash memory, static random access memory (SRAM), etc.), and a secondary memory (e.g., a data storage device 1418), which may communicate with each other via a bus 1430.

Processing device 1402 represents one or more general-purpose processing devices such as a microprocessor, central processing unit, or the like. Processing device 1402 includes processing logic 1426. Processing device 1402 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 1402 may also be one or more special-purpose processing devices such as an application specific integrated circuit (ASIC), a field programmable gate array (FPGA), a digital signal processor (DSP), network processor, or the like. In accordance with one or more aspects of the present disclosure, processing device 1402 may be configured to execute instructions implementing example process 600 of mitigation of wafer stress and deformation and/or example process 700 of ion implantation performed for mitigation of wafer stress and deformation.

Example computer system 1400 may further comprise a network interface device 1408, which may be communicatively coupled to a network 1420. Example computer system 1400 may further comprise a video display 1410 (e.g., a liquid crystal display (LCD), a touch screen, or a cathode ray tube (CRT)), an alphanumeric input device 1412 (e.g., a keyboard), a cursor control device 1414 (e.g., a mouse), and an acoustic signal generation device 1416 (e.g., a speaker).

Data storage device 1418 may include a computer-readable storage medium (or, more specifically, a non-transitory computer-readable storage medium) 1424 on which is stored one or more sets of executable instructions 1422. In accordance with one or more aspects of the present disclosure, executable instructions 1422 may comprise executable instructions implementing example process 600 of mitigation of wafer stress and deformation and/or example process 700 of ion implantation performed for mitigation of wafer stress and deformation.

Executable instructions 1422 may also reside, completely or at least partially, within main memory 1404 and/or within processing device 1402 during execution thereof by example computer system 1400, main memory 1404 and processing device 1402 also constituting computer-readable storage media. Executable instructions 1422 may further be transmitted or received over a network via network interface device 1408.

While the computer-readable storage medium 1424 is shown in FIG. 14 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “identifying,” “determining,” “storing,” “adjusting,” “causing,” “returning,” “comparing,” “creating,” “stopping,” “loading,” “copying,” “throwing,” “replacing,” “performing,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Examples of the present disclosure also relate to an apparatus for performing the methods described herein. This apparatus may be specially constructed for the required purposes, or it may be a general purpose computer system selectively programmed by a computer program stored in the computer system. Such a computer program may be stored in a computer readable storage medium, such as, but not limited to, any type of disk including optical disks, CD-ROMs, and magnetic-optical disks, read-only memories (ROMs), random access memories (RAMs), EPROMs, EEPROMs, magnetic disk storage media, optical storage media, flash memory devices, other type of machine-accessible storage media, or any type of media suitable for storing electronic instructions, each coupled to a computer system bus.

The methods and displays presented herein are not inherently related to any particular computer or other apparatus. Various general purpose systems may be used with programs in accordance with the teachings herein, or it may prove convenient to construct a more specialized apparatus to perform the required method steps. The required structure for a variety of these systems will appear as set forth in the description below. In addition, the scope of the present disclosure is not limited to any particular programming language. It will be appreciated that a variety of programming languages may be used to implement the teachings of the present disclosure.

It is to be understood that the above description is intended to be illustrative, and not restrictive. Many other implementation examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A method to correct an out-of-plane deformation of a substrate, the method comprising:
identifying, using optical inspection data, a profile of the out-of-plane deformation of the substrate;
performing a polynomial decomposition of the identified profile to determine a plurality of polynomial coefficients, each of the plurality of polynomial coefficients characterizing a respective one of a plurality of elemental deformation shapes of the substrate;
identifying, based on at least a subset of the plurality of polynomial coefficients, one or more characteristics of a stress-compensation layer (SCL) for the substrate;
causing the SCL to be deposited on the substrate;
performing a plurality of statistical simulations to identify settings for a non-uniform stress-mitigation irradiation of the SCL, wherein performing the plurality of statistical simulations comprises sampling from one or more statistical distributions associated with previously performed stress-mitigation irradiations; and
performing the non-uniform stress-mitigation irradiation of the SCL using the identified settings, wherein the non-uniform stress-mitigation irradiation is performed using at least first settings for a first region of the SCL and second settings for a second region of the SCL.

2. The method of claim 1, wherein the plurality of elemental deformation shapes of the substrate comprises a paraboloid deformation of the substrate and a saddle deformation of the substrate.

3. The method of claim 2, wherein the polynomial decomposition of the identified profile comprises decomposition of the identified profile over Zernike polynomials.

4. The method of claim 1, wherein the one or more characteristics of the SCL comprise one or more of:
a material of the SCL, or
a thickness of the SCL.

5. The method of claim 1, wherein the identified settings comprise one or more of:
a type of particles of a stress-mitigation beam used for the non-uniform stress-mitigation irradiation of the SCL,
an energy of the particles of the stress-mitigation beam, or
an angle of incidence of the particles of the stress-mitigation beam on the SCL.

6. The method of claim 1, wherein the SCL causes the substrate to overcorrect the out-of-plane deformation of the substrate, and wherein the non-uniform stress-mitigation irradiation causes mitigation of the overcorrected out-of-plane deformation of the substrate.

7. The method of claim 1, wherein the non-uniform stress-mitigation irradiation of the SCL comprises an ion implantation, and wherein the one or more statistical distributions comprise at least one of:
a distribution of depths of the ion implantation for one or more types of ions and/or one or more energies of the ions, or
a distribution of a number of generated vacancies for one or more types of ions and/or one or more energies of the ions.

8. The method of claim 7, wherein one or more of the distribution of depths or the distribution of the number of generated vacancies depend on an angle of incidence of the ions on the SCL.

9. A system comprising:
a memory; and
a processing device communicatively coupled to the memory, the processing device to:
identify, using optical inspection data, a profile of an out-of-plane deformation of a substrate;
perform a polynomial decomposition of the identified profile to determine a plurality of polynomial coefficients, each of the plurality of polynomial coefficients characterizing a respective one of a plurality of elemental deformation shapes of the substrate;
identify, based on at least a subset of the plurality of polynomial coefficients, one or more characteristics of a stress-compensation layer (SCL) for the substrate;
causing the SCL to be deposited on the substrate;
perform a plurality of statistical simulations to identify settings for a non-uniform stress-mitigation irradiation of the SCL, wherein performing the plurality of statistical simulations comprises sampling from one or more statistical distributions associated with previously performed stress-mitigation irradiations; and
perform the non-uniform stress-mitigation irradiation of the SCL using the identified settings, wherein the non-uniform stress-mitigation irradiation is performed using at least first settings for a first region of the SCL and second settings for a second region of the SCL.

10. The system of claim 9, wherein the plurality of elemental deformation shapes of the substrate comprises a paraboloid deformation of the substrate and a saddle deformation of the substrate.

11. The system of claim 9, wherein the polynomial decomposition of the identified profile comprises decomposition of the identified profile over Zernike polynomials.

12. The system of claim 9, wherein the one or more characteristics of the SCL comprises one or more of:
a material of the SCL, or
a thickness of the SCL.

13. The system of claim 9, wherein the identified settings comprise one or more of:
a type of particles of a stress-mitigation beam used for the non-uniform stress-mitigation irradiation of the SCL,
an energy of the particles of the stress-mitigation beam, or
an angle of incidence of the particles of the stress-mitigation beam on the SCL.

14. The system of claim 9, wherein the SCL causes the substrate to overcorrect the out-of-plane deformation of the substrate, and wherein the non-uniform stress-mitigation irradiation causes mitigation of the overcorrected out-of-plane deformation of the substrate.

15. The system of claim 9, wherein the non-uniform stress-mitigation irradiation of the SCL comprises an ion implantation, and wherein the one or more statistical distributions comprise at least one of:
a distribution of depths of the ion implantation for one or more types of ions and/or one or more energies of the ions, or
a distribution of a number of generated vacancies for one or more types of ions and/or one or more energies of the ions.

16. The system of claim 15, wherein one or more of the distribution of depths or the distribution of the number of generated vacancies depend on an angle of incidence of the ions on the SCL.

17. A semiconductor manufacturing system comprising:
one or more processing chambers to process a substrate; and
a computing device to:
identify, using optical inspection data, a profile of an out-of-plane deformation of a substrate;
perform a polynomial decomposition of the identified profile to determine a plurality of polynomial coefficients, each of the plurality of polynomial coefficients characterizing a respective one of a plurality of elemental deformation shapes of the substrate;
identify, based on at least a subset of the plurality of polynomial coefficients, one or more characteristics of a stress-compensation layer (SCL) for the substrate;
causing the SCL to be deposited on the substrate;
perform a plurality of statistical simulations to identify settings for a non-uniform stress-mitigation irradiation of the SCL, wherein performing the plurality of statistical simulations comprises sampling from one or more statistical distributions associated with previously performed stress-mitigation irradiations; and
perform the non-uniform stress-mitigation irradiation of the SCL using the identified settings, wherein the non-uniform stress-mitigation irradiation is performed using at least first settings for a first region of the SCL and second settings for a second region of the SCL.

18. The semiconductor manufacturing system of claim 17, wherein the one or more characteristics of the SCL comprises one or more of:
a material of the SCL, or
a thickness of the SCL.

19. The semiconductor manufacturing system of claim 17, wherein the identified settings comprise one or more of:
a type of particles of a stress-mitigation beam used for the non-uniform stress-mitigation irradiation of the SCL,
an energy of the particles of the stress-mitigation beam, or
an angle of incidence of the particles of the stress-mitigation beam on the SCL.

20. The semiconductor manufacturing system of claim 17, wherein the non-uniform stress-mitigation irradiation of the SCL comprises an ion implantation, and wherein the one or more statistical distributions comprise at least one of:
a distribution of depths of the ion implantation for one or more types of ions and/or one or more energies of the ions, or
a distribution of a number of generated vacancies for one or more types of ions and/or one or more energies of the ions.
